(19) United States
(12) Patent Application Publication
(10) Pub. No.: US 2020/0106056 A1
(43) Pub. Date: Apr. 2, 2020

(54) ETCHING DEVICE

(71) Applicant: Sharp Kabushiki Kaisha, Sakai City, Osaka (JP)

(72) Inventors: Hiroki TANIYAMA, Sakai City (JP); Tohru OKABE, Sakai City (JP); Shinsuke SAIDA, Sakai City (JP); Shinji ICHIKAWA, Sakai City (JP); Ryosuke GUNJI, Sakai City (JP); Yoshihiro NAKADA, Sakai City (JP); Akira INOUE, Sakai City (JP); Hiroharu JINMURA, Sakai City (JP)

(21) Appl. No.: 16/469,171

(22) PCT Filed: Sep. 4, 2017
(86) PCT No.: PCT/JP2017/031799

§ 371 Date: Jun. 13, 2019

(51) Int. Cl. H01L 51/56; H01L 51/00

(52) U.S. Cl. CPC H01L 51/56; H01L 51/5206; H01L 51/0023

(57) ABSTRACT

An etching device includes a chemical treatment tank configured to allow a substrate to be transported in an interior thereof, and a spraying unit disposed in the interior of the chemical treatment tank, including a blowing port oriented in a direction that does not intersect a front face of the substrate, and configured to spray an etchant chemical solution as a mist through the blowing port.

### TECHNICAL FIELD

The disclosure relates to an etching device and to a manufacturing method of a display device.

### BACKGROUND ART

In PTL 1, there is disclosed an organic electroluminescent (EL) display panel in which a non-fixed side substrate includes a recessed portion provided with an EL element unit positioned in an interior of the recessed portion, and peripheral edges formed as ribs. This recessed portion is formed by etching performed by supplying an etching solution as a mist.

In PTL 2, there is disclosed a mist etching method configured so that an existing structure serves as a used masking member that was exposed on a front face of a semiconductor wafer and used as a mask having etching resistance in a prior etching step, and the used masking member is to be dissolved by mist-etching. In this mist etching method, the etching solution used is a micromist formed by making the etching solution into fine particles and dispersing the particles as a mist in an inert gas.

### CITATION LIST

### Patent Literature

PTL 1: JP 2004-186042 A

PTL 2: JP 2009-010033 A

### SUMMARY

### Technical Problem

According to the configurations of PTL 1 and PTL 2, variation occurs in a thickness of an etchant liquid film formed on a front face of the substrate, making it problematically difficult to accurately etch the substrate.

The disclosure is made to solve the above-described problems, and an object of the disclosure is to achieve accurate etching of the substrate.

### Solution to Problem

To solve the above-described problems, an etching device according to an aspect of the disclosure includes a chemical treatment tank configured to allow a substrate to be transported in an interior thereof, and a spraying unit disposed in the interior of the chemical treatment tank, including a blowing port oriented in a direction that does not intersect a front face of the substrate, and configured to spray an etchant chemical solution as a mist through the blowing port.

To solve the above-described problems, a manufacturing method of a display device according to another aspect of the disclosure includes transporting a substrate in an interior of a chemical treatment tank, and causing a spraying unit disposed in the interior of the chemical treatment tank and including a blowing port oriented in a direction that does not intersect a front face of the substrate to spray an etchant chemical solution as a mist through the blowing port.

### Advantageous Effects of Disclosure

According to an aspect of the disclosure, the effect of making it possible to accurately etch a substrate is achieved.

### BRIEF DESCRIPTION OF DRAWINGS

FIG. 1 is a diagram illustrating a configuration of an etching device.

FIG. 2 is a diagram illustrating a configuration of a cooling tank.

FIG. 3 is a diagram illustrating a configuration of a chemical treatment tank.

FIG. 4 is a diagram illustrating a configuration of a cleaning tank.

FIG. 5 is a diagram illustrating a configuration of a drying tank.

FIG. 6 is a diagram illustrating a configuration of an unloader.

FIG. 7 is a diagram illustrating a more detailed configuration of the chemical treatment tank.

FIG. 8 is a diagram illustrating a substrate transported in an inclined state in an interior of the chemical treatment tank.

### DESCRIPTION OF EMBODIMENTS

### Configuration of Etching Device 1

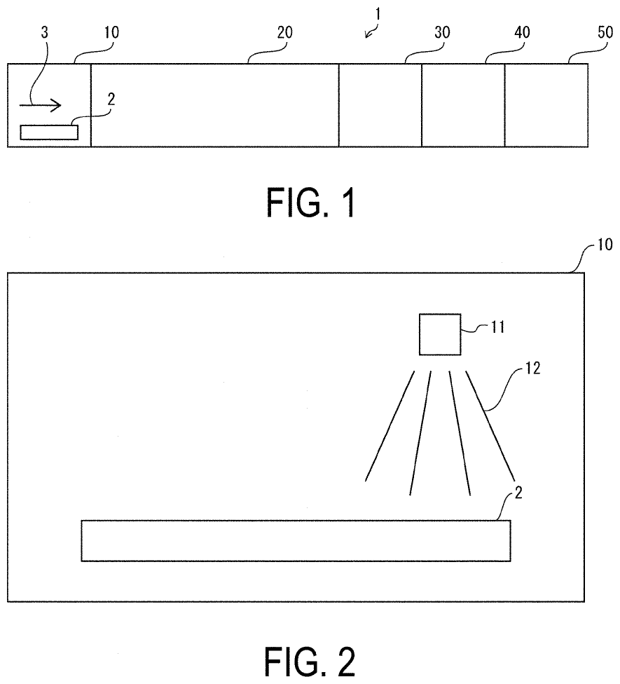

FIG. 1 is a diagram illustrating a configuration of an etching device 1. The etching device 1 is a device configured to etch a front face of a substrate 2. The substrate 2 is, for example, a substrate in which constituent elements of a display device, such as an organic EL display device, are formed on the front face thereof. The etching device 1 wet-etches the substrate 2 to form a wiring line using indium tin oxide (ITO)/silver (Ag)/ITO as the material on the front face of the substrate 2, for example.

The etching device 1 of FIG. 1 includes a cooling tank 10, a chemical treatment tank 20, a cleaning tank 30, a drying tank 40, and an unloader 50. The cooling tank 10 to the unloader 50 are aligned in a row, in order. The substrate 2 is first transported into the cooling tank 10. The etching device 1 transports the substrate 2 in a certain transport direction 3 using a transport roller (not illustrated). In FIG. 1, the transport direction 3 of the substrate 2 is a linear direction from the cooling tank 10 toward the unloader 50.

The etching device 1 transports the substrate 2 to the cooling tank 10, the chemical treatment tank 20, the cleaning tank 30, the drying tank 40, and the unloader 50, in that order, and specific processing related to etching is performed on the substrate 2 at each location. The etching device 1 cools the substrate 2 in the cooling tank 10, chemically treats (etches) the substrate 2 in the chemical treatment tank 20, cleans the substrate 2 in the cleaning tank 30, and dries the substrate 2 in the drying tank 40. Lastly, the etching device 1 removes the substrate 2 from the unloader 50 to an exterior of the etching device 1.

### Cooling of Substrate 2

FIG. 2 is a diagram illustrating a configuration of the cooling tank 10. The cooling tank 10 is disposed upstream of the chemical treatment tank 20 in the etching device 1, and includes a cooling unit 11 in an interior thereof. The cooling unit 11 is a type of air blower that delivers cooling air 12. A blowing port of the cooling unit 11 faces the substrate 2. The cooling tank 10 also serves as a loader. The loader is a device that first arranges the substrate 2 to be etched in the etching device 1 in an interior of the etching device 1. The etching device 1 transports the substrate 2 by the transport roller from an inlet of the cooling tank 10 toward an outlet of the cooling tank 10. During this period, the cooling unit 11 blows the cooling air 12 toward the substrate 2. The substrate 2 is cooled by the cooling air 12, and thus a temperature of the substrate 2 is reduced. The etching device 1 cools the substrate 2 to a temperature at least 5° C. lower than an atmospheric temperature, for example. The etching device 1 transports the cooled substrate 2 from the cooling tank 10 to an interior of the chemical treatment tank 20.

### Chemical Treatment of Substrate 2

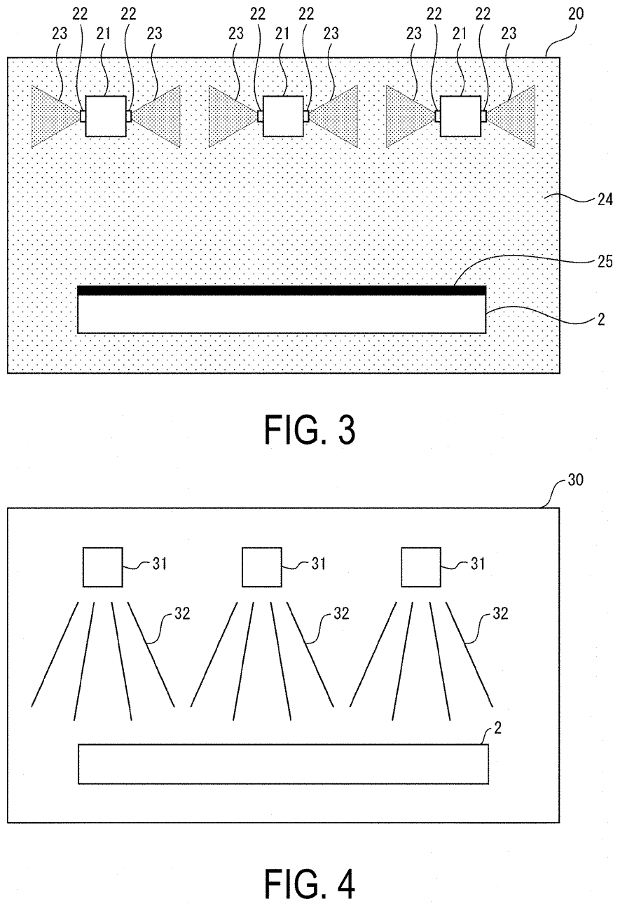

FIG. 3 is a diagram illustrating a configuration of the chemical treatment tank 20. The chemical treatment tank 20 is disposed upstream of the cleaning tank 30 in the etching device 1, and includes a plurality of humidifying unit 21 (spraying unit) in the interior thereof. The plurality of humidifying units 21 are arranged aligned in a row in the transport direction 3 of the substrate 2, in the interior of the chemical treatment tank 20. The humidifying units 21 each include a blowing port 22 not facing the substrate 2. In FIG. 1, the blowing port 22 of the humidifying unit 21 faces a direction parallel with the transport direction 3 of the substrate 2. The humidifying unit 21 is a type of a humidifier that sprays a chemical solution 23 as a mist through the blowing port 22 into the interior of the chemical treatment tank 20. The chemical solution 23 is an etchant for etching the front face of the substrate 2.

The humidifying units 21 each spray the chemical solution 23 as a mist through the blowing port 22 in the interior of the chemical treatment tank 20. The timing of the spray may be before or after the substrate 2 is transported into the humidifying unit 21. The etching device 1 controls a temperature of the chemical solution 23 to be sprayed in accordance with the type of the chemical solution 23. The temperature of the chemical solution 23 is a temperature at least 10° higher than an atmospheric temperature of the etching device 1, and is, for example, from 40° C. to 42° C.

The sprayed chemical solution 23 is diffused in the interior of the chemical treatment tank 20. When a sufficient amount of the chemical solution 23 is sprayed, the interior of the chemical treatment tank 20 is filled with a saturated steam amount of chemical mist 24. The chemical mist 24 uniformly adheres to the front face of the substrate 2. As a result, a thin liquid film 25 having a uniform thickness is formed on the front face of the substrate 2. The front face of the substrate 2 is etched by the liquid film 25, and a predetermined wiring line pattern is formed on the front face of the substrate 2. The etching device 1 transports the substrate 2 on the front face of which the liquid film 25 of the chemical solution 23 partially remains from the chemical treatment tank 20 to an interior of the cleaning tank 30.

### Cleaning of Substrate 2

FIG. 4 is a diagram illustrating a configuration of the cleaning tank 30. The cleaning tank 30 is disposed upstream of the drying tank 40 in the etching device 1, and includes a plurality of cleaning units 31. The cleaning units 31 are each a type of water discharging device that discharges a cleaning water 32 for cleaning the substrate 2. The plurality of cleaning units 31 are aligned in a row in the transport direction 3 of the substrate 2. A blowing port of the cleaning unit 31 faces the substrate 2.

The cleaning units 31 each discharge the cleaning water 32 toward the substrate 2 transported into the interior of the cleaning tank 30. The liquid film 25 on the front face of the substrate 2 is washed off by the cleaning water 32, thereby removing a residual chemical solution on the front face. The etching device 1 transports the substrate 2 wetted by the cleaning water 32 from the cleaning tank 30 to an interior of the drying tank 40.

### Drying of Substrate 2

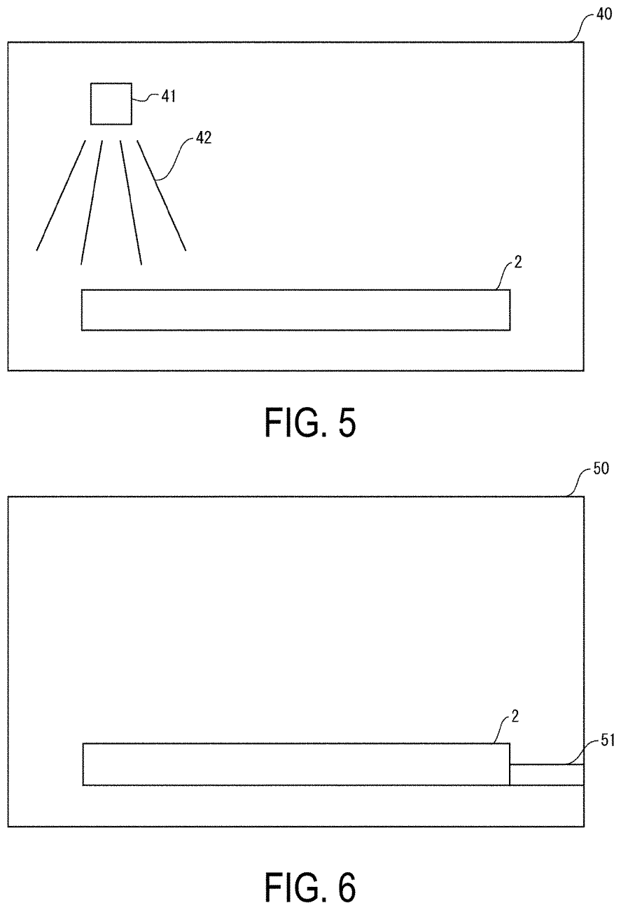

FIG. 5 is a diagram illustrating a configuration of the drying tank 40. The drying tank 40 is disposed upstream of the unloader 50 in the etching device 1, and includes a drying unit 41 in an interior thereof. The drying unit 41 is a type of air blower that delivers drying air 42. A blowing port of the drying unit 41 faces the substrate 2. The etching device 1 blows the drying air 42 from the drying unit 41 to the substrate 2 transported into the interior of the drying tank 40. Moisture adhering to the front face of the substrate 2 is evaporated by the drying air 42 blown onto the front face. The etching device 1 continues the blowing of the drying air 42 for a certain period of time until the substrate 2 is sufficiently dried. When the drying treatment of the substrate 2 is completed, the etching device 1 transports the substrate 2 from the drying tank 40 to an interior of the unloader 50.

### Removal of Substrate 2

FIG. 6 is a diagram illustrating a configuration of the unloader 50. The unloader 50 is disposed downstream of the cleaning tank 30 in the etching device 1, and includes a removal mechanism 51. The removal mechanism 51 is a part for removing the substrate 2 to the exterior of the etching device 1. The etching device 1 removes the substrate 2 transported into the unloader 50 to the exterior of the etching device 1 by using the removal mechanism 51. This completes the etching of the etching device 1.

### Advantages of Etching Device 1

According to the present embodiment, advantages such as the following are achieved.

The blowing port 22 of the chemical solution 23 does not face the substrate 2, and thus the sprayed chemical solution 23 does not strongly collide with the front face of the substrate 2. As a result, an amount of the chemical mist 24 adhering to the front face of the substrate 2 is prevented from becoming non-uniform in accordance with a position of the front face, making it possible to form a uniform liquid film 25 on the entire front face of the substrate 2. Thus, an etching shift amount on the substrate 2 can be made consistent regardless of the position on the front face of the substrate 2, making it possible to uniformly etch the front face of the substrate 2. As a result, a wiring line having a uniform width can be formed on the front face of the substrate 2. Further, a process window free of residue spreads on the front face of the substrate 2, making it possible to improve a yield during manufacture of the display device.

The mist-like chemical solution 23 is used for etching the substrate 2, making it possible to reduce a usage amount of the chemical solution 23. As a result, an etching cost can be reduced.

The substrate 2 is sufficiently cooled before being etched, allowing the chemical mist 24 to readily condense on the front face of the substrate 2. As a result, the liquid film 25 can be formed in a stable manner on the front face of the substrate 2.

### Detailed Configuration of Chemical Treatment Tank 20

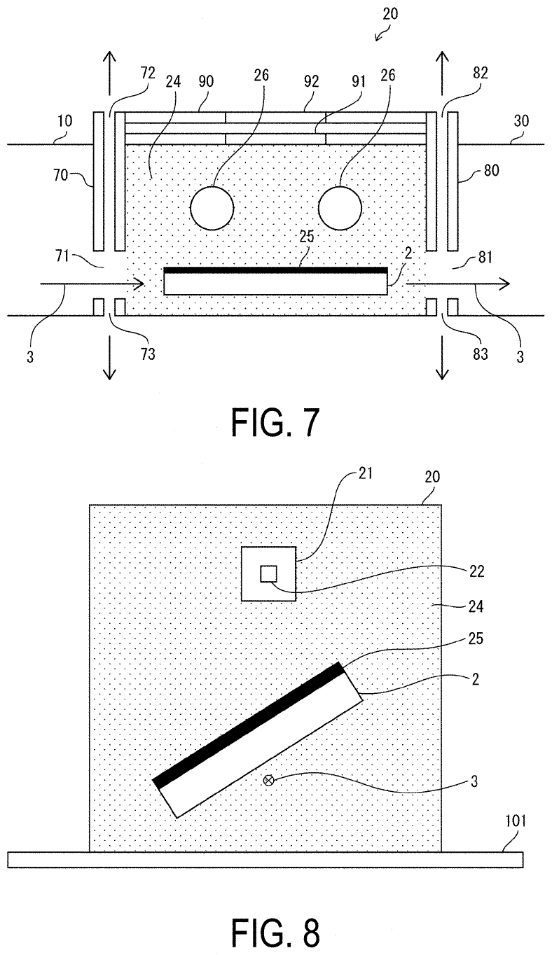

FIG. 7 is a diagram illustrating a more detailed configuration of the chemical treatment tank 20. The chemical treatment tank 20 of FIG. 7 includes, in addition to the humidifying units 21 illustrated in FIG. 3, a plurality of exhaust ports 26, an incoming door 70, an outgoing door 80, and a ceiling 90. The plurality of exhaust ports 26 are provided on a side face of the chemical treatment tank 20, the side face being disposed in a direction orthogonal to the transport direction 3. The incoming door 70 and the outgoing door 80 are respectively disposed on an incoming side and an outgoing side of the chemical treatment tank 20 relative to the substrate 2. The ceiling 90 is disposed on an uppermost portion of the chemical treatment tank 20.

The incoming door 70 is a double door with a gap formed in an interior thereof. An inlet 71 that passes through the double door is formed in the incoming door 70. The inlet 71 is a passage for the substrate 2 when the substrate 2 is transported into the chemical treatment tank 20. An exhaust port 72 and an exhaust port 73 are respectively formed in an upper portion and a lower portion of the incoming door 70. The outgoing door 80 is a double door with a gap formed in an interior thereof. An outlet 81 that passes through the double door is formed in the outgoing door 80. The outlet 81 is a passage for the substrate 2 when the substrate 2 is transported from the chemical treatment tank 20. An exhaust port 82 and an exhaust port 83 are respectively formed in an upper portion and a lower portion of the outgoing door 80. The ceiling 90 includes a ceiling door 91 and a ceiling door 92.

The inlet 71 of the incoming door 70 is opened during transport of the substrate 2 from the cooling tank 10 to the chemical treatment tank 20. At this time, the etching device 1 emits the chemical mist 24 to the exterior of the etching device 1 by a minimum suction force that does not allow the chemical mist 24 to leak into the cooling tank 10 through the exhaust port 72 and the exhaust port 73 of the incoming door 70. Thus, the chemical mist 24 can be prevented from flowing into the cooling tank 10 during the transport of the substrate 2 from the cooling tank 10, making it possible to increase a safety of the cooling tank 10.

The outlet 81 of the outgoing door 80 is opened during transport of the substrate 2 from the chemical treatment tank 20 to the cleaning tank 30. At this time, the etching device 1 emits the chemical mist 24 to the exterior of the etching device 1 by a minimum suction force that does not allow the chemical mist 24 to leak into the cleaning tank 30 through the exhaust port 82 and the exhaust port 83 of the outgoing door 80. Thus, the chemical mist 24 can be prevented from flowing into the cleaning tank 30 during the transport of the substrate 2 from the chemical treatment tank 20, making it possible to increase a safety of the cleaning tank 30.

A manager of the etching device 1 opens the ceiling door 92 during maintenance of the chemical treatment tank 20. At this time, the ceiling door 91 is closed, and thus the manager is not exposed to the chemical mist 24 inside the chemical treatment tank 20. The etching device 1 emits the chemical mist 24 filled in the chemical treatment tank 20 to the exterior of the chemical treatment tank 20 via the exhaust port 26 with the opening of the ceiling door 92 serving as a trigger. When the chemical mist 24 is sufficiently emitted, the etching device 1 unlocks the ceiling door 91. As a result, the manager can open the ceiling door 91. When the ceiling door 91 is opened, the chemical mist 24 does not exist in the chemical treatment tank 20, and thus the manager is not exposed to the chemical mist 24. Accordingly, the manager can safely maintain the interior of the chemical treatment tank 20.

### Other

The chemical treatment tank 20 preferably includes as many humidifying units 21 as possible. The greater the number of humidifying units 21, the more quickly the interiors of the humidifying units 21 can be filled with the chemical mist 24.

The etching device 1 can control a depth of the etching by changing a transport speed of the substrate 2 inside the humidifying units 21. For example, a stagnation time of the substrate 2 inside the chemical treatment tank 20 increases when the transport speed of the substrate 2 is further slowed, making it possible to deepen the etching. The etching can be further deepened by temporarily stopping the substrate 2 in the interior of the mist-like chemical treatment tank 20.

FIG. 8 is a diagram illustrating the substrate 2 transported in an inclined state in the interior of the chemical treatment tank 20. As illustrated in FIG. 8, the etching device 1 can transport the substrate 2 in an inclined state as viewed from the transport direction 3 of the substrate 2, in the interior of the chemical treatment tank 20. In this case, a planar direction of the substrate 2 is parallel with the transport direction 3 of the substrate 2, and is inclined relative to a lower face 101 of the chemical treatment tank 20. In a case where the substrate 2 thus inclined is transported as well, the liquid film 25 having a uniform thickness in the humidifying units 21 is consistently formed on the front face of the substrate 2, making it possible to uniformly etch the substrate 2.

The humidifying units 21 may be disposed on a horizontal side of the substrate 2 in the chemical treatment tank 20. In this configuration as well, the blowing ports of the humidifying units 21 are consistently not oriented toward the substrate 2.

The cooling units 11 may each be configured as a cooler that cools the substrate 2 by making the cooling water come into contact with a rear face of the substrate 2.

### Supplement

Aspect 1: An etching device, including a chemical treatment tank configured to allow a substrate to be transported in an interior thereof, and a spraying unit disposed in the interior of the chemical treatment tank, including a blowing port oriented in a direction that does not intersect a front face of the substrate, and configured to spray an etchant chemical solution as a mist through the blowing port.

Aspect 2: The etching device according to aspect 1, wherein the blowing port of the spraying unit faces a direction parallel with a transport direction of the substrate.

Aspect 3: The etching device according to aspect 1 or 2, wherein a plurality of the spraying units are disposed in the interior of the chemical treatment tank.

Aspect 4: The etching device according to any one of aspects 1 to 3, further including a cooling unit disposed upstream of the chemical treatment tank, and configured to cool the substrate prior to transport into the chemical treatment tank.

Aspect 5: The etching device according to aspect 4, wherein the cooling unit is configured to cool the substrate to a temperature at least 5° C. lower than an atmospheric temperature of the etching device.

Aspect 6: The etching device according to any one of aspects 1 to 5, wherein the substrate is transported in an inclined state as viewed from the transport direction of the substrate, in the interior of the chemical treatment tank.

Aspect 7: The etching device according to any one of aspects 1 to 6, wherein the spraying unit is configured to spray the etchant chemical solution at a temperature at least 10° C. higher than an atmospheric temperature of the etching device.

Aspect 8: The etching device according to any one of aspects 1 to 7, wherein the substrate is temporarily stopped in the interior of the chemical treatment tank.

Aspect 9: A manufacturing method of a display device, including transporting a substrate in an interior of a chemical treatment tank, and causing a spraying unit disposed in the interior of the chemical treatment tank and including a blowing port oriented in a direction that does not intersect a front face of the substrate to spray an etchant chemical solution as a mist through the blowing port.

The disclosure is not limited to the embodiments described above, various changes can be made within the scope indicated in the claims. Embodiments obtained by appropriately combining technical approaches stated in each of the different embodiments also fall within the scope of the technology of the disclosure. Novel technical features may also be formed by combining the technical approaches stated in each of the embodiments.

### REFERENCE SIGNS LIST

1 Etching device
2 Substrate
3 Transport direction
10 Cooling tank
11 Cooling unit
12 Cooling air
20 Chemical treatment tank
21 Humidifying unit
22 Blowing port
23 Chemical solution
24 Chemical mist
25 Liquid film
26, 72, 73, 82, 83 Exhaust port
30 Cleaning tank
31 Cleaning unit
32 Cleaning water
40 Drying tank
41 Drying unit
42 Drying air
50 Unloader
51 Mechanism
70 Incoming door
71 Inlet
80 Outgoing door
81 Outlet
90 Ceiling
91, 92 Ceiling door
101 Lower face of chemical treatment tank

1-3, (canceled)

4. An etching device comprising:
a chemical treatment tank configured to allow a substrate to be transported in an interior thereof,
a spraying unit disposed in the interior of the chemical treatment tank, including a blowing port oriented in a direction that does not intersect a front face of the substrate, and configured to spray an etchant chemical solution as a mist through the blowing port; and
the etching device a cooling unit disposed upstream of the chemical treatment tank, and configured to cool the substrate prior to transport into the chemical treatment tank.

5. The etching device according to claim 4,
wherein the cooling unit is configured to cool the substrate to a temperature at least 5° C. lower than an atmospheric temperature of the etching device.

6. The etching device according to 4,
wherein the substrate is transported in an inclined state as viewed from the transport direction of the substrate, in the interior of the chemical treatment tank.

7. The etching device according to claim 4,
wherein the spraying unit is configured to spray the etchant chemical solution at a temperature at least 10° C. higher than an atmospheric temperature of the etching device.

8. The etching device according to claim 4,
wherein the substrate is temporarily stopped in the interior of the chemical treatment tank.

9. (canceled)

10. The etching device according to claim 4,
wherein the blowing port faces a direction parallel with a transport direction of the substrate.

11. The etching device according to claim 4,
wherein a plurality of the spraying units are disposed in the interior of the chemical treatment tank.
